(19) United States
(12) Patent Application Publication
(10) Pub. No.: US 2004/0235228 A1
(43) Pub. Date: Nov. 25, 2004

(54) System and method for depositing a graded carbon layer to enhance critical layer stability

(76) Inventors: PR. Chidambaram, Richardson, TX (US); Srinivasan Chakravarthi, Richardson, TX (US); Haowen Bu, Plano, TX (US)

Correspondence Address: TEXAS INSTRUMENTS INCORPORATED, P O BOX 655474, M/S 3999, DALLAS, TX, 75265

(21) Appl. No.: 10/444,054

(22) Filed: May 22, 2003

(51) Int. Cl. H01L 21/336; H01L 21/8238; H01L 21/302; H01L 21/461

(52) U.S. Cl. 438/199; 438/285

(57) ABSTRACT

A method for fabricating a complimentary metal-oxide semiconductorg (CMOS) device (100) has the steps of providing a substrate (102) and forming a layer of Silicon-Germanium-Carbon (SiGeC) (104) over the substrate (102). The layer of SiGeC (104) has between about 0.001 to 2 percent C by weight. The C concentration in the layer of SiGeC (104) is changed while forming the layer of SiGeC (104).

### TECHNICAL FIELD OF THE INVENTION

This invention generally relates to a system and method for depositing a graded carbon layer to enhance critical layer stability in CMOS devices.

### BACKGROUND OF THE INVENTION

Without limiting the scope of the invention, its background is described in connection with semiconductor manufacturing and is best exemplified by methods and processes for fabricating CMOS devices. The term “MOS” is an acronym for metal-oxide semiconductor and is used in this application, in its conventional sense, to refer to any insulated-gate-field-effect-transistor, or to integrated circuits (ICs) that include such transistors. A MOS structure is typically formed by depositing various layers of conducting and insulating materials to form transistors on a silicon substrate. Two common types of transistors are NMOS and PMOS. The term “NMOS” is used in this application to refer to a MOS device having negatively charged regions that conduct extra electrons through the structure. The term “PMOS” is used in this application to refer to a MOS device having components that conduct electrons through positively charged holes. The term “CMOS” is an acronym for complimentary metal-oxide semiconductor. CMOS describes a complimentary formation of NMOS and PMOS devices formed on a common substrate.

Typical CMOS transistors are formed on a pure silicon (Si) substrate, which forms a channel region of the transistor. Recent discoveries have indicated that introducing stress into the silicon substrate enhances performance of the channel region because electrons may move more freely through a stressed silicon structure. Incorporation of atoms of a different element, such as germanium, for example, changes the stress in the silicon. On a molecular level, impurities within the silicon lattice strain the silicon bonds, which cause stress in the silicon structure and allows electrons to move more freely. Germanium (Ge), for example, may be used to strain the silicon lattice and improve performance of a device.

A brief explanation of how the silicon-germanium region enhances device performance is provided below. The application of germanium in the silicon channel region of a CMOS device, for example, results in the formation of a non-uniform energy gap. This non-uniform gap reduces transit time and thus increases the device speed. More particularly, the energy gap in the silicon can be varied by the introduction of dopants, the formation of alloys (e.g., SiGe), and/or the introduction of strain into the crystal lattice. Combinations of all three of these phenomena have been used to produce very high speed graded SiGe-base heterojunction bipolar transistors (HBT's). In addition, such graded profile heterojunction bipolar transistors may exhibit additional advantages over conventional silicon devices for high speed digital and microwave devices, for example, by providing higher emitter injection efficiency, lower base resistance, lower base transit times, and superior low temperature speed and gain. Generally, the device response time is faster because electrons move with less resistance through the semiconductor structures.

In many common CMOS fabrication processes, however, multiple or intense thermal processes may be required. These fabrication processes have what is commonly known as a high thermal budget. A high thermal budget is essentially multiple or long duration high heat processes that are performed during the CMOS fabrication process. These thermal processes may cause diffusion of dopants into a silicon-germanium region because of the inherent lattice mismatch between the silicon and the germanium. During thermal processes, heat can cause movement in the structure of the silicon-germanium region and dopants or other impurities tend to diffuse into and fill the spaces caused by the lattice mismatch. Desired electrical properties of the silicon-germanium region may, therefore, be diminished or destroyed.

Another problem that occurs during CMOS fabrication is realignment or movement of germanium within the silicon lattice structure during thermal processes. This realignment may cause strain relaxation, which is detrimental to device performance. Because strain within the lattice structure enhances the performance of the device, it is desirable to maintain strain in the silicon-germanium layer. This strain, however, cannot be maintained while fabricating devices that have a high thermal budget.

For example, high-temperature anneal processes used in fabricating polysilicon devices may result in the P-type dopant (e.g., boron) diffusing into the base region. Annealing is heating the device at high temperatures to relieve any stress within the lattice structure of the device. At temperature of about 600 degrees Celcius (C), for example, atoms within the device tend to become mobile and realign to a less stressed state. Consequently, impurities, such as dopants, tend to diffuse out of the silicon. To mitigate the negative impact of such diffusion, a silicon buffer layer is typically added to the base region to prevent dopant diffusion from negatively impacting the silicon-germanium alloy. Such a buffer layer, however, causes the effective device thickness to increase, which is not desirable.

Consequently, there is a need in the art for an improved method of fabricating CMOS devices that does not promote diffusion during the necessary thermal processes. Additionally, there is a need for an improved method of fabricating CMOS devices that does not degrade device performance as a result of the necessary thermal processes.

### SUMMARY OF THE INVENTION

The present invention includes a method for fabricating a CMOS device having the steps of providing a substrate and forming a layer of Silicon-Germanium-Carbon (SiGeC) over the substrate. The layer of SiGeC typically has between about 0.001 to 2 percent carbon by weight. The carbon concentration in the layer of SiGeC is changed while forming the layer of SiGeC. Changes in the carbon concentration allow the device to maintain performance characteristics during subsequent thermal processes.

One embodiment of the present invention is a method of controlling critical layer strain during fabrication of a CMOS device including the steps of providing a substrate and forming a first layer of SiGeC over the substrate. The concentration of carbon in the first layer of SiGeC is selectively varied while the first layer of SiGeC is formed. A second layer of SiGeC is formed over the first layer of SiGeC. The concentration of carbon in the second layer of SiGeC is selectively varied while the second layer of SiGeC is formed.

Another embodiment of the present invention is a layered structure for forming a CMOS device therein. The layered structure has a substrate and one or more layers of SiGeC over the substrate. In this embodiment, the one or more layers of SiGeC have a graded carbon profile.

Therefore, in accordance with the previous summary, objects, features and advantages of the present invention will become apparent to one skilled in the art from the subsequent description and the appended claims taken in conjunction with the accompanying drawings.

### BRIEF DESCRIPTION OF THE FIGURES

For a more complete understanding of the present invention, reference is now made to the detailed description of the invention taken in conjunction with the accompanying drawings in which like numerals identify like parts and in which:

FIG. 1 is a schematic diagram of the cross section of a CMOS device according to the prior art;

FIG. 2 is a schematic diagram of the cross section of a CMOS device according to one embodiment of the present invention;

FIG. 3 is a schematic diagram of the cross section of a CMOS device according to one embodiment of the present invention;

FIG. 4 is a schematic diagram of the cross section of a CMOS device according to one embodiment of the present invention;

FIG. 5 is a schematic diagram of the cross section of a CMOS device according to another embodiment of the present invention; and

FIG. 6 is a schematic diagram of the cross section of a CMOS device according to yet another embodiment of the present invention.

### DETAILED DESCRIPTION OF THE INVENTION

While the making and using of various embodiments of the present invention are discussed in detail below, it should be appreciated that the present invention provides many applicable inventive concepts that may be embodied in a wide variety of specific context. The specific embodiments discussed herein are merely illustrative of specific ways to make and use the invention and do not delimit the scope of the invention.

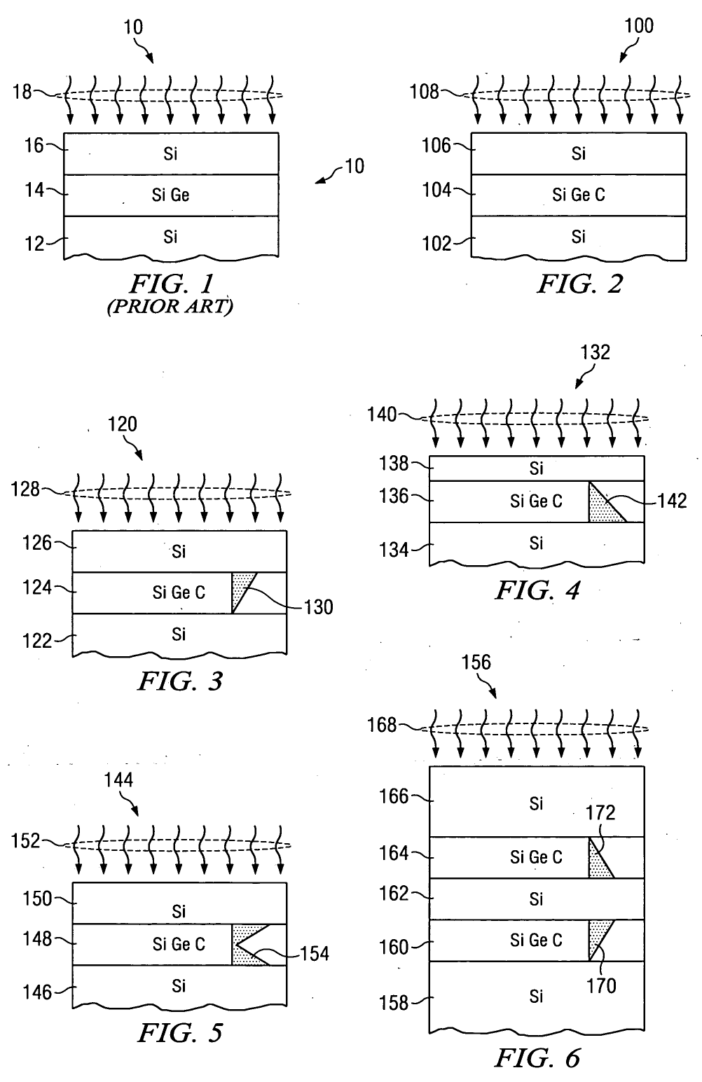

In FIG. 1, the cross section of a CMOS device 10 according to the prior art is depicted. A silicon substrate 12 is used as the foundation of the CMOS device 10. The silicon substrate 12 may be doped with impurities such as boron, for example, to enhance the electrical performance of the CMOS device 10. A layer 14 of silicon-germanium is formed over the silicon substrate 12 and may be used to form different components of the CMOS device 10 such as transistor gates, for example. A layer 16 of silicon may be formed over the layer 14 of silicon-germanium during a subsequent fabrication process. A heat treatment process 18, such as an anneal step, for example, may be performed on the CMOS device 10. The heat treatment process 18 may cause any dopant that was added to the silicon substrate 12 to diffuse into the layer 14 of silicon-germanium. This detrimental result reduces the electrical characteristics of the silicon substrate 12. Additionally, the heat treatment process 18 may relax the strain in the layer 14 of silicon-germanium.

As discussed above, the strain, which is a result of the lattice structure mismatch caused when germanium is placed in the silicon lattice structure, enhances the performance of the silicon-germanium layer 14. Relaxing the strain as a result of the heat treatment process 18 is however, detrimental to the performance of the CMOS device 10.

Referring now to FIG. 2, therein is disclosed one embodiment of the present invention, in which a CMOS device 100 has a silicon substrate 102. The silicon substrate 102 may be doped with various dopants such as boron, for example, to enhance the electrical performance of the CMOS device 100. A layer 104 of silicon-germanium-carbon (SiGeC) may be formed over the silicon substrate 102. The layer 104 of SiGeC may be from about 10 nm (nanometers) to about 100 nm thick and may be formed by chemical vapor deposition (CVD), for example. Other methods of forming the layer 104 of SiGeC will be apparent to those having ordinary skill in the art of semiconductor fabrication. A layer 106 of silicon may be deposited over the layer 104 of SiGeC, again, using conventional fabrication techniques.

The layer 104 of SiGeC may have from about 15 to 25 percent germanium by weight. Other amounts of germanium may be used according to the amount of strain desired in the layer 104 of SiGeC and the required stability of the layer 104 of SiGeC. The percentage of carbon in the layer 104 of SiGeC may be varied from about 0.001 percent to about 2 percent carbon by weight. The amount of carbon in the SiGeC layer 104 may be varied according to the desired performance characteristics during subsequent thermal processes 108. For example, if the CMOS device 100 has a high thermal budget, more carbon can be added to the SiGeC layer 104 to inhibit diffusion of dopants or impurities into the SiGeC layer 104. Additionally, greater percentages of carbon in the SiGeC layer 104 can reduce strain relaxation in the SiGeC layer 104 during subsequent thermal processes.

Turning now to FIGS. 3-5, several embodiments of CMOS devices 120, 132, 144 according to the present invention are depicted. Specifically, in FIG. 3 the CMOS device 120 has a silicon substrate 122. Regions of the silicon substrate 122 may be doped with N-type or P-type impurities according to desired characteristics of a particular region.

A layer 124 of SiGeC may be deposited over the silicon substrate 122. The layer 124 of SiGeC may be about 10 nm to about 100 nm thick and may be deposited by chemical vapor deposition or other methods and processes known to those having ordinary skill in the art of semiconductor fabrication. Additionally, a layer 126 of silicon may be formed over the SiGeC layer 124. The CMOS device 120 may be subjected to one or more heat treatment processes 128, such as an annealing process, for example.

The SiGeC layer 124 may have a carbon profile 130, which may be formed according to various fabrication processes that are used to manufacture the CMOS device 120. In this particular example, the carbon profile 130 has a lower concentration of carbon near the silicon substrate 122 and a higher carbon concentration near the silicon layer 126. The amount of carbon deposited in various strata of the SiGeC layer 124 during the formation of the SiGeC layer 124 may be continuously adjusted using a mass-flow device, which is commonly used for semiconductor fabrication. One example of a mass-flow device is a MKS Model M330 Mass Flow Controller (MFC) for semiconductor fabrication processes, which is manufactured by MKS Instruments, Inc. As a result of adjusting the amount of carbon deposited during fabrication, more carbon may be present initially in the upper portions of the SiGeC layer 124 than in the lower portions.

Carbon is used in the SiGeC layer 124 because carbon atoms are the proper size to most effectively fit within the strained silicon-germanium lattice structure. Germanium atoms are larger than silicon atoms and therefore create a misfit lattice, which results in the desired performance-enhancing, strained structure. Thermal processes 128, however, tend to diffuse the germanium and relieve strain within the silicon-germanium lattice. Carbon, because it is smaller than silicon, counters the misfit between the silicon and germanium and relaxes the strain. Subsequent thermal processes 128 cause the carbon to diffuse out of the silicon-germanium lattice structure, which reintroduces the performance-enhancing strain into the CMOS device 120.

The amount of carbon in various portions of the SiGeC layer 124 can be adjusted according to particular fabrication requirements or characteristics. For example, the carbon profile 130 of CMOS device 120 is optimized for a low thermal budget and to prevent defect formation as a result of strain relaxation. Because of the low thermal budget, the carbon is located near the upper portion of the SiGeC layer 124. This allows a large portion of the carbon to diffuse out of the CMOS device 120 by the completion of the thermal processes 128 because the carbon is generally located near the top surface of the CMOS device 120. After a substantial portion of the carbon has diffused from the SiGeC layer 124, the lattice strain in the SiGeC layer 124 returns. Additionally, the presence of carbon in the SiGeC layer 124 inhibits defect formation during thermal processes 128 because the carbon effectively fills any lattice mismatch voids and buffers any shift in the lattice that would cause defects.

Turning now to FIG. 4, a CMOS device 132 that has a high thermal budget is depicted. The CMOS device 132 is formed on a silicon substrate 134, which may be implanted with N-type or P-type dopants according to the desired characteristics of the CMOS device 132. A layer 136 of SiGeC is formed over the silicon substrate 134 and a layer 138 of silicon may be formed over the layer 136 of SiGeC. The SiGeC layer 136 may have from about 15 to 25 percent germanium by weight and from about 0.001 percent to 2 percent carbon by weight. The SiGeC layer 136 may be from about 10 nm to about 100 nm thick. One or more thermal processes 140, such as an anneal process, for example, may be performed on the CMOS device 132.

A carbon profile 142 is optimized for a high thermal budget and to prevent diffusion of the germanium into the silicon substrate 134. The carbon profile 142 provides for a higher concentration of carbon in the lower portion of the SiGeC layer 136 and a lower concentration of carbon in the upper portion of the SiGeC layer 136. A lower carbon concentration in the lower portion of the SiGeC layer 136 allows the carbon to gradually diffuse out of the CMOS device 132 over the span of the thermal processes 140. Additionally, the carbon retards diffusion of the germanium into the silicon substrate 134.

Referring now to FIG. 5, a CMOS device 144 that has a silicon substrate 146 is depicted. The silicon substrate 146 may be implanted with N-type or P-type dopants according to the desired characteristics of the CMOS device 144. A layer 148 of SiGeC is formed over the silicon substrate 146 and a layer 150 of silicon may be formed over the layer 148 of SiGeC. The SiGeC layer 148 may have about 20 percent germanium by weight and from about 0.001 percent to 2 percent carbon by weight in this embodiment. The SiGeC layer 148 may be from about 10 nm to about 100 nm thick. One or more thermal processes 152, such as an anneal example, may be performed on the CMOS device 144.

In this particular example, a carbon profile 154 is depicted as having a high carbon concentration near the silicon substrate 146. The carbon concentration is gradually reduced near the middle of the layer and then increases towards the silicon layer 150. Other carbon concentrations within the SiGeC layer are contemplated according to particular design or process characteristics of the CMOS device 144. For example, the carbon content of the SiGeC layer 148 may be continuously varied during formation of the SiGeC layer 148.

Turning now to FIG. 6, a CMOS device 156 according to one embodiment of the present invention is depicted. The CMOS device 156 is formed on a silicon substrate 158. A layer of SiGeC 160 is formed over the silicon substrate 158 by chemical vapor deposition (CVD) or other known method of forming a layer of material over a substrate. Alternating layers of silicon 162, 166 may be formed over the layers of SiGeC 160, 164. Four layers are depicted in this particular example, however, other numbers of alternating layers of SiGeC and silicon may be incorporated into the CMOS device 156 according to particular fabrication or performance requirements of the CMOS device 156. Each layer of SiGeC 160, 164 may have a different carbon profile 170, 172 according to the requirements of a particular thermal budget or fabrication process.

Although this invention has been described with reference to illustrative embodiments, this description is not intended to limit the scope of the invention. Various modifications and combinations of the illustrative embodiments as well as other embodiments of the invention will be apparent to persons skilled in the art upon reference to the description. It is therefore intended that the appended claims accomplish any such modifications or embodiments.

What is claimed is:

1. A method for fabricating a CMOS device comprising the steps of:
providing a substrate;
forming a layer of Silicon-Germanium-Carbon (SiGeC) over the substrate, the layer of SiGeC having between about 0.001 to 2 percent carbon by weight; and
changing the carbon concentration in the layer of SiGeC while forming the layer of SiGeC.

2. The method of claim 1, further comprising the step of forming a layer of Si over the layer of SiGeC.

3. The method of claim 1, wherein the layer of SiGeC contains approximately 0.02 percent C by weight.

4. The method of claim 1, wherein the layer of SiGeC contains approximately 20 percent Ge by weight.

5. The method of claim 1, wherein the layer of SiGeC is between about 10 nm to about 100 nm thick.

6. The method of claim 2, further comprising the step of thermally processing the layer of Si.

7. The method of claim 1, wherein the step of changing the C concentration is changing the C concentration from a lower portion of the layer of SiGeC to an upper portion of the layer of SiGeC.

8. The method of claim 7, wherein the C concentration in the layer of SiGeC is increased from about 0.001 percent C by weight in the lower portion of the layer of SiGeC to about 2 percent C by weight in the upper portion of the layer of SiGeC.

9. The method of claim 7, wherein the C concentration in the layer of SiGeC is decreased from about 2 percent C by weight in the lower portion of the layer of SiGeC to about 0.001 percent C by weight in the upper portion of the layer of SiGeC.

10. The method of claim 1, further comprising the step of diffusing at least a portion of the C out of the SiGeC layer by a thermal process.

11. A method of controlling critical layer strain during fabrication of a CMOS device comprising the steps of:
providing a substrate;
forming a first layer of Silicon-Germanium-Carbon (SiGeC) over the substrate;
selectively varying the concentration of C in the first layer of SiGeC while forming the first layer of SiGeC;
forming a second layer of SiGeC over the first layer of SiGeC; and selectively varying the concentration of C in the second layer of SiGeC while forming the second layer of SiGeC.

12. The method of claim 11, wherein the first layer of SiGeC contains approximately 0.02 percent C by weight.

13. The method of claim 11, wherein the first and second layers of SiGeC contain approximately 20 percent Ge by weight.

14. The method of claim 11, wherein the first layer of SiGeC is between about 10 nm to about 100 nm thick.

15. The method of claim 11, further comprising the step of forming a layer of Si over the second layer of SiGeC.

16. The method of claim 15, further comprising the step of diffusing at least a portion of the C out of the second layer of SiGeC by a thermal process.

17. The method of claim 11, wherein selectively varying the amount of C in the first layer of SiGeC is by selectively varying the amount of C from a lower portion of the first layer of SiGeC to an upper portion of the first layer of SiGeC.

18. The method of claim 17, wherein the amount of C in the first layer of SiGeC is increased from about 0.001 percent C by weight in the lower portion of the first layer of SiGeC to about 2 percent C by weight in the upper portion of the first layer of SiGeC.

19. The method of claim 17, wherein the amount of C in the first layer of SiGeC is decreased from about 2 percent C by weight in the lower portion of the first layer of SiGeC to about 0.001 percent C by weight in the upper portion of the first layer of SiGeC.

20. A layered structure for forming a CMOS device therein, comprising:
a substrate; and
one or more layers of Silicon-Germanium-Carbon (SiGeC) over the substrate, the one or more layers of SiGeC having a graded C profile.

21. The layered structure of claim 20, wherein the one or more layers of SiGeC contain approximately 0.02 percent C by weight.

22. The layered structure of claim 20, wherein the one or more layers of SiGeC contain approximately 20 percent Ge by weight.

23. The layered structure of claim 20, wherein the one or more layers of SiGeC are between about 10 nm to about 100 nm thick.

24. The layered structure of claim 20, further comprising a layer of Si over the one or more layers of SiGeC.

25. The layered structure of claim 20, wherein the C profile of the one or more layers of SiGeC generally begins at a lower portion of the one or more layers of SiGeC and generally ends at an upper portion of the one or more layers of SiGeC.

26. The layered structure of claim 25, wherein the C in the one or more layers of SiGeC increases from about 0.001 percent C by weight in the lower portion to about 2 percent C by weight in the upper portion.

27. The layered structure of claim 25, wherein the C in the one or more layers of SiGeC decreases from about 2 percent C by weight in the lower portion to about 0.001 percent C by weight in the upper portion.

28. A method for fabricating a CMOS device comprising the steps of:
providing a substrate; and
forming two or more layers of Silicon-Germanium-Carbon (SiGeC) over the substrate, each of the two or more layers of SiGeC having between about 0.001 to 2 percent C by weight.

29. The method of claim 28, further comprising the step of forming a layer of Si over at least one layer of SiGeC.

30. The method of claim 28, wherein the two or more layers of SiGeC each contain approximately 0.02 percent C by weight.

31. The method of claim 28, wherein the two or more layers of SiGeC each contain approximately 20 percent Ge by weight.

32. The method of claim 28, wherein each of the two or more layers of SiGeC are between about 10 nm to about 100 nm thick.

33. The method of claim 29, further comprising the step of thermally processing the layer of Si.

34. The method of claim 29, further comprising the step of changing the C concentration while forming the two or more layers of SiGeC.

35. The method of claim 34, wherein the step of changing the C concentration is changing the C concentration from a lower portion of the two or more layers of SiGeC to an upper portion of the two or more layers of SiGeC.

36. The method of claim 34, wherein the C concentration in the two or more layers of SiGeC is increased from about 0.001 percent C by weight in the lower portion of the two or more layers of SiGeC to about 2 percent C by weight in the upper portion of the two or more layers of SiGeC.

37. The method of claim 34, wherein the C concentration in the two or more layers of SiGeC is decreased from about 2 percent C by weight in the lower portion of the two or more layers of SiGeC to about 0.001 percent C by weight in the upper portion of the two or more layers of SiGeC.

38. The method of claim 28, further comprising the step of diffusing at least a portion of the C out of the two or more layers of SiGeC by a thermal process.
